(19) United States
(12) Patent Application Publication
(10) Pub. No.: US 2025/0386624 A1
(43) Pub. Date: Dec. 18, 2025

(54) MICRO LED ELEMENT, MICRO LED DISPLAY PANEL AND DISPLAY DEVICE

(71) Applicant: JADE BIRD DISPLAY (SHANGHAI) LIMITED, SHANGHAI (CN)

(72) Inventors: Zhichen GU, Shanghai (CN); Weisin TAN, Shanghai (CN)

(21) Appl. No.: 19/235,589

(22) Filed: Jun. 12, 2025

(30) Foreign Application Priority Data
Jun. 14, 2024 (WO) PCT/CN2024/099206

(51) Int. Cl. H10H 20/857; H01L 25/075; H10H 20/819; H10H 20/833; H10H 20/84

(52) U.S. Cl. CPC H10H 20/857; H01L 25/0753; H10H 20/819; H10H 20/833; H10H 20/84

(57) ABSTRACT

A micro LED element, a micro LED display panel, and a display device are provided. The micro LED element includes: a first semiconductor layer, a light emitting layer, and a second semiconductor layer stacked from top down; and a metal contact including a plurality of metal particles conductively coupled to the top surface of the first semiconductor layer.

### CROSS-REFERENCE TO RELATED APPLICATIONS

The present disclosure claims the benefit of priority to PCT Application No. PCT/CN2024/099206, filed on Jun. 14, 2024, which is incorporated herein by reference in its entirety.

### TECHNICAL FIELD

The present disclosure generally relates to micro display technology, and more particularly, to a micro light emitting diode (LED) element, a micro LED display panel, and a display device.

### BACKGROUND

Inorganic micro pixel light emitting diodes, also referred to as micro light emitting diodes, micro LEDs, or μ-LEDs, become more important since they are used in various applications including self-emissive micro-displays, visible light communications, and optogenetics. The micro LEDs have higher output performance than conventional LEDs because of better strain relaxation, improved light extraction efficiency, and uniform current spreading. Compared with conventional LEDs, the micro LEDs also exhibit several advantages, such as improved thermal effects, faster response rate, larger working temperature range, higher resolution, wider color gamut, higher contrast, lower power consumption, and operability at higher current density.

A micro LED display panel is manufactured by integrating an array of thousands or even millions of micro LEDs with an integrated circuit (IC) back panel. In conventional techniques, a metal contact for increasing electrical conductivity may be arranged on the top surface of a micro LED. Since the metal contact is arranged in the emitting path of light generated by the micro LED, it may deteriorate the displaying quality of the micro LED.

Therefore, there is a need for improving the displaying quality of micro LEDs.

### SUMMARY OF THE DISCLOSURE

Some embodiments of the present disclosure provide a micro LED element. The micro LED element includes: a first semiconductor layer, a light emitting layer, and a second semiconductor layer stacked from top down; and a metal contact comprising a plurality of metal particles conductively coupled to the top surface of the first semiconductor layer.

Some embodiments of the present disclosure provide a micro LED display panel. The micro LED display panel includes an integrated circuit (IC) backplane including a common pad and a plurality of bottom contacts; and a plurality of micro LED elements disposed on a top surface of the IC backplane, each according to any of the micro LED described herein, and wherein: the transparent conductive layer is conductively coupled to the common pad; and the contact pad is formed to contact a corresponding bottom contact of the plurality of bottom contacts.

Some embodiments of the present disclosure provide a display device. The display device includes any of the micro LED described herein or any of the micro LED display panels described herein.

### BRIEF DESCRIPTION OF THE DRAWINGS

Embodiments and various aspects of the present disclosure are illustrated in the following detailed description and the accompanying figures. Various features shown in the figures are not drawn to scale.

FIG. 1 illustrates a structural diagram showing a sectional view of an exemplary micro LED element, according to some embodiments of the present disclosure.

FIG. 2 illustrates a structural diagram showing a sectional view of another exemplary micro LED element, according to some embodiments of the present disclosure.

FIG. 3A illustrates a structural diagram showing a sectional view of an exemplary micro LED display panel, according to some embodiments of the present disclosure.

FIG. 3B illustrates a structural diagram showing a sectional view of another exemplary micro LED display panel, according to some embodiments of the present disclosure.

FIG. 4 illustrates a structural diagram showing a sectional view of another exemplary micro LED display panel, according to some embodiments of the present disclosure.

FIG. 5A illustrates a structural diagram showing a sectional view of another exemplary micro LED element, according to some embodiments of the present disclosure.

FIG. 5B illustrates a structural diagram showing a sectional view of another exemplary micro LED element, according to some embodiments of the present disclosure.

FIG. 6 illustrates a structural diagram showing a sectional view of another exemplary micro LED display panel, according to some embodiments of the present disclosure.

FIG. 7 illustrates a structural diagram showing a sectional view of another exemplary micro LED element, according to some embodiments of the present disclosure.

FIG. 8 illustrates a structural diagram showing a sectional view of another exemplary micro LED display panel, according to some embodiments of the present disclosure.

FIG. 9 illustrates a structural diagram showing a sectional view of another exemplary micro LED display panel, according to some embodiments of the present disclosure.

FIG. 10 illustrates an exemplary display device, according to some embodiments of the present disclosure.

FIG. 11 illustrates another exemplary display device, according to some embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the invention. Instead, they are merely examples of apparatuses and methods consistent with aspects related to the invention as recited in the appended claims. Particular aspects of the present disclosure are described in greater detail below. The terms and definitions provided herein control, if in conflict with terms and/or definitions incorporated by reference.

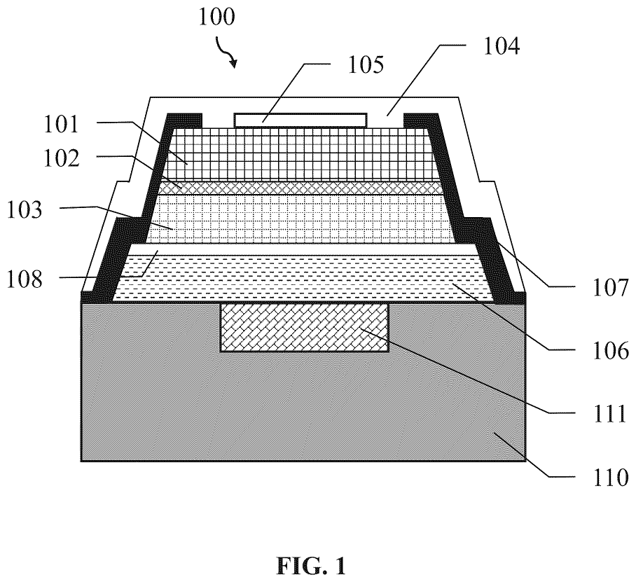

FIG. 1 illustrates a structural diagram showing a sectional view of an exemplary micro LED element 100, according to some embodiments of the present disclosure. Referring to FIG. 1, micro LED element 100 includes a first semiconductor layer 101, a light emitting layer 102, and a second semiconductor layer 103. First semiconductor layer 101, light emitting layer 102, and second semiconductor layer 103 are stacked from top down to form a mesa. The sidewall of the mesa is inclined. A transparent conductive layer 104 is formed on a top surface of first semiconductor layer 101 and is conductively coupled to first semiconductor layer 101. A metal contact 105 is embedded in transparent conductive layer 104 and can provide an ohmic contact to increase the electrical conductivity between first semiconductor layer 101 and transparent conductive layer 104. Transparent conductive layer 104 is connected to an electrode (not shown, e.g., a common pad) of IC (integrated circuit) backplane 110. The mesa further includes a contact pad 106 that is connected to an electrode 111 (e.g., a Cu pad) of an IC backplane 110. Hence, transparent conductive layer 104 and contact pad 106 are connected to two electrodes of IC backplane 110 either directly or indirectly. This enables first semiconductor layer 101 and second semiconductor layer 103 to receive signals from IC backplane 110 via transparent conductive layer 104 and contact pad 106, respectively. As a consequence, light emitting layer 102 between first semiconductor layer 101 and second semiconductor layer 103 can be driven by IC backplane 110.

With further reference to FIG. 1, a sidewall surface of the mesa is covered with a passivation layer 107 for providing electrical insulation to the components within the mesa. In some embodiments, the mesa may further include a transparent conductive layer 108 for conductively connecting second semiconductor layer 103 and contact pad 106. The presence of metal contact 105 along an emitting path of light generated by light emitting layer 102 may result in a shading effect, thus reducing light extraction. Moreover, metal contact 105 can also have an impact on the far-field beam profile of micro LED element 100.

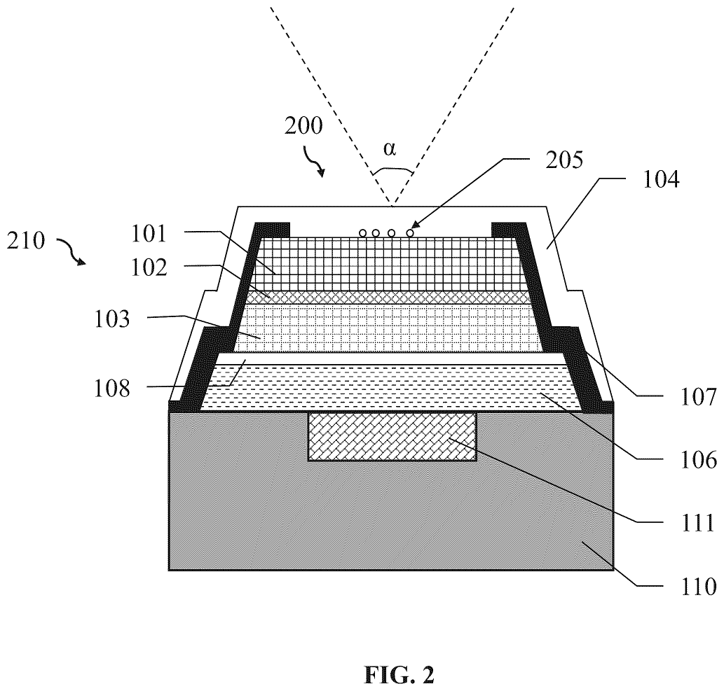

FIG. 2 illustrates a structural diagram showing a sectional view of another exemplary micro LED element 200, according to some embodiments of the present disclosure. Referring to FIG. 2, micro LED element 200 includes a mesa 210, which includes first semiconductor layer 101, light emitting layer 102, and second semiconductor layer 103 as described with reference to FIG. 1. First semiconductor layer 101, light emitting layer 102, and second semiconductor layer 103 are stacked from top down to form mesa 210. As can be seen from FIG. 2, the sidewall of mesa 210 is inclined.

In some embodiments, second semiconductor layer 103 can be a P-type epitaxial layer or an N-type epitaxial layer. First semiconductor layer 101 is an N-type epitaxial layer or a P-type epitaxial layer. A material of first semiconductor layer 101 is selected from one or more of GaN, InGaN, AlInGaN, AlGaN, GaP, AlGaInP, or AlInP. Light emitting layer 102 is a quantum well layer. A material of light emitting layer 102 is selected from one or more of InGaN, AlGaN, AlInGaN, InGaP or AlGaInP. First semiconductor layer 101 and second semiconductor layer 103 have opposite conductive types. That is, if first semiconductor layer 101 is a P-type epitaxial layer, then second semiconductor layer 103 is an N-type epitaxial layer; and if first semiconductor layer 101 is an N-type epitaxial layer, then second semiconductor layer 103 is a P-type epitaxial layer. A material of second semiconductor layer 103 is selected from one or more of AlInP, AlGaInP, GaP, GaN, InGaN, AlInGaN or AlGaN.

In some embodiments, micro LED element 200 includes transparent conductive layer 104 formed on a top surface of first semiconductor layer 101 and is conductively coupled to first semiconductor layer 101. A metal contact 205 is embedded in transparent conductive layer 104 and can increase the electrical conductivity between first semiconductor layer 101 and transparent conductive layer 104. As illustrated in FIG. 2, metal contact 205 includes a plurality of metal particles (also referred to as a “metal agglomeration” as the metal particles may be generated by heating a metal pad into cohesive units, which is denoted by hollow circles) conductively coupled to the top surface of first semiconductor layer 101. For example, micro LED element 200 can be a red micro LED element used to represent a red pixel or sub-pixel. As described above, the presence of metal contact 105 as a whole pad in red micro LED element can result in an undesirable shading effect, a decrease in light extraction, or a blurred far-field beam profile. With the introduction of metal contact 205 composed of metal particles, the contacting area with first semiconductor layer 101 can be reduced while maintaining the ohmic-contact between first semiconductor layer 101 and transparent conductive layer 104.

Moreover, the introduction of metal contact 205 including metal particles will increase the proportion of light within a divergence angle (e.g., twenty degrees, denoted as “α” in FIG. 2) of micro LED element 200. Consequently, an improvement in light energy power and an increase in light extraction efficiency can be expected at a viewer's eye. For example, when micro LED element 200 is incorporated into a pair of AR/VR glasses, the divergence angle of micro LED element 200 is concentrated when coupling to a waveguide of the AR/VR glasses.

Metal contact 205 having metal particles can be formed in a variety of ways. For example, the metal particles can be deposited on first semiconductor layer 101 by sputtering or electron-beam deposition. As another example, the metal particles can be etched from a metal pad attached to first semiconductor layer 101. In some embodiments, a thickness of metal contact 205 having metal particles can be less than 100 nm. That is, the height of each metal agglomeration constructing metal contact 205 can be less than 100 nm.

In some embodiments, a size of each metal particle can be less than 500 nm. Herein, the size of an object refers to the largest measurable dimension of the object. For example, if a particle is generated as a cuboid, then the size of the particle can be the length of the longest diagonal of the cuboid. If a particle is spherically generated, then the size of the particle can be the diameter of the spheric. As can be appreciated, if a particle is ellipsoidally generated, then the size of the particle can be the length of the longest, i.e., major, axis of the ellipsoid.

In some embodiments, a distribution diameter of the metal particles in the transparent conductive layer 104 is within a range from 700 nm to 800 nm. That is, the metal particles are generated and distributed within a generally circular area with a diameter of 700 nm to 800 nm (e.g., 720 nm, 750 nm, or 780 nm) on the top surface of first semiconductor layer 101.

In some embodiments, a distribution density of the metal particles in the transparent conductive layer 104 is within a range from 10/μm² to 10000/μm². For example, there can be thirty particles generated and distributed within an area of one μm² on the top surface of first semiconductor layer 101 and the corresponding distribution density will be 30/μm².

In some embodiments, the diameter of a top surface of mesa 210 is smaller than the diameter of a bottom surface of mesa 210. That is, the sidewall of mesa 210 inclines so that mesa 210 gradually becomes narrower from bottom to top. The inclined sidewall can be generated in other forms which are not described herein. The principal description above can also be applied to these variants.

As mesa 210 can be formed by etching at certain angles, the widths of different layers will be different due to the etching mechanism. In an etching process, the upper layers are made narrower than the lower layers. In some embodiments, the diameter of the top surface of the mesa 210 can be similar to, or the same as, the diameter of the bottom surface. That is, the sidewall of mesa can be almost vertical.

Still referring to FIG. 2, mesa 210 further includes transparent conductive layer 108 as described above with reference to FIG. 1. Second semiconductor layer 103 is formed on a top surface of transparent conductive layer 108. Light emitting layer 102 is formed on second semiconductor layer 103, and first semiconductor layer 101 is formed on light emitting layer 102.

In some embodiments, transparent conductive layer 108 is provided as a TCO (transparent conductive oxide) layer, for example, an ITO (Indium Tin Oxide) layer, an AZO (Aluminium doped Zinc Oxide) layer, a GZO (Gallium doped Zinc Oxide), an ATO (Antimony doped Tin Oxide) layer, an FTO (Fluorine doped Tin Oxide) layer, or the like. In some embodiments, transparent conductive layer 104 can be formed with the same material as transparent conductive layer 108.

As shown in FIG. 2, passivation layer 107 is formed on a sidewall surface of mesa 210. The thickness of passivation layer 107 is in a range of 3 nm to 15 nm for a bule micro LED element 200 or a green micro LED element 200, e.g., the thickness of passivation layer 107 can be 3 nm, 4 nm, 5 nm, 6 nm, 7 nm, 8 nm, 9 nm, 10 nm, 11 nm, 12 nm, 13 nm, 14 nm, or 15 nm. Alternatively, the thickness of passivation layer 107 can be several hundred nanometers for a red micro LED element 200. In some examples, passivation layer 107 is an ALD (Atomic Layer Deposition)-based layer or formed by plasma-enhanced chemical vapor deposition (PECVD). A material of passivation layer 107 can be selected from one or more of Al₂O₃, HfN, SiO₂, or SiN. Passivation layer 107 is used as a thin dielectric layer. It prevents shorting of N-type epitaxial layer and P-type epitaxial layer and passivates dangling bonds on mesa sidewalls to reduce leakage current in micro LED element 200. As shown in FIG. 2, passivation layer 107 can also be deposited in a region of the top surface of mesa 210, specifically a periphery of the top surface of first semiconductor layer 101. Transparent conductive layer 104 is formed on the top surface of mesa 210 in the region that is not deposited with passivation layer 107. Transparent conductive layer 104 can be further formed on a surface of the passivation layer 107 in the process of deposition.

The other aspects of micro LED element 200 can be understood by referring to the description of micro LED element 100 with reference to FIG. 1 and will not be described in detail here.

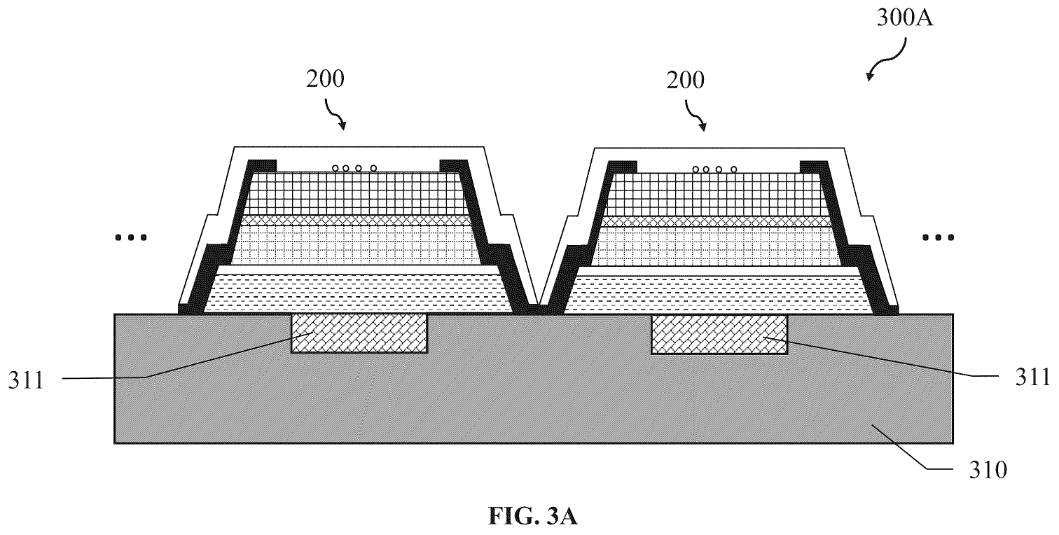

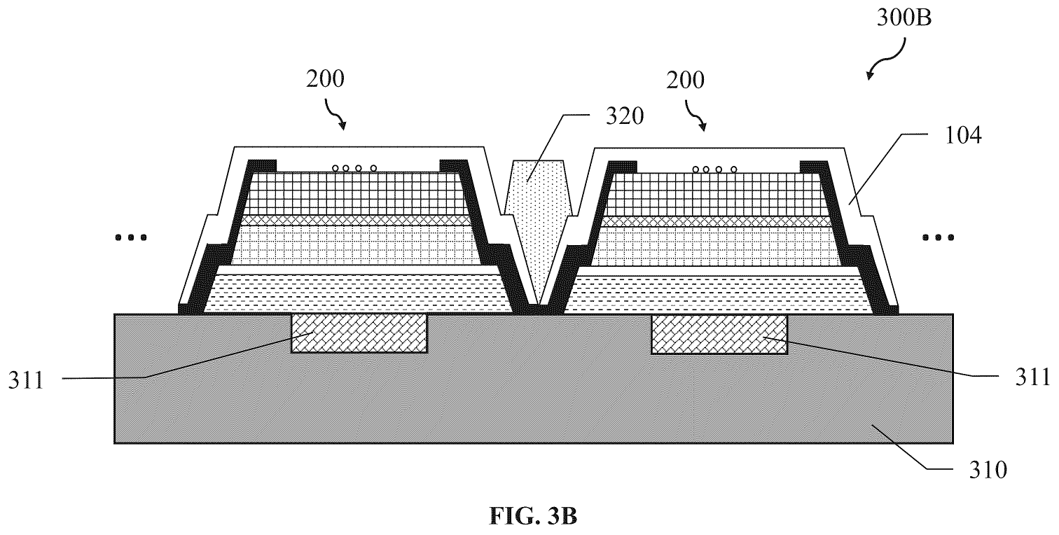

FIG. 3A illustrates a structural diagram showing a sectional view of an exemplary micro LED display panel 300A, according to some embodiments of the present disclosure. As shown in FIG. 3A, micro LED display panel 300A includes an integrated circuit (IC) backplane 310 (e.g., corresponding to IC backplane 110 in FIGS. 1 and 2). A plurality of electrodes 311 (e.g., corresponding to electrode 111 in FIGS. 1 and 2) is embedded in IC backplane 310 such that one electrode corresponds to one micro LED element 200. Micro LED display panel 300A further includes a plurality of micro LED elements 200 as described above with reference to FIG. 2. Each of the plurality of micro LED elements 200 is disposed on a top surface of IC backplane 310. In the present disclosure, the top surface of IC backplane 310 is a surface that can be provided as a substrate for arranging components. As can be appreciated, the top surface, or its corresponding bottom surface on the opposite side, is typically larger than other sides of the IC backplane.

It can be understood that in FIG. 3A, micro LED display panel 300A including two micro LED elements 200 is shown only for illustrative purposes. The structure shown can be extended to form a complete micro LED display panel 300A. In some embodiments, micro LED display panel 300A may further include an insulating layer (not shown) formed on IC backplane 310 between each of the plurality of micro LED elements 200. The insulating layer can cover IC backplane 310 and provide insulation to surface components of IC backplane 310.

FIG. 3B illustrates a structural diagram showing a sectional view of another exemplary micro LED display panel 300B, according to some embodiments of the present disclosure. As shown in FIG. 3B, a metal pad 320 disposed on transparent conductive layer 104 and between adjacent micro LED elements 200 can be used to increase current expansion between adjacent micro LED elements 200.

The other aspects of micro LED display panel 300B can be understood by referring to the description of micro LED display panel 300A with reference to FIG. 3A and will not be described in detail here.

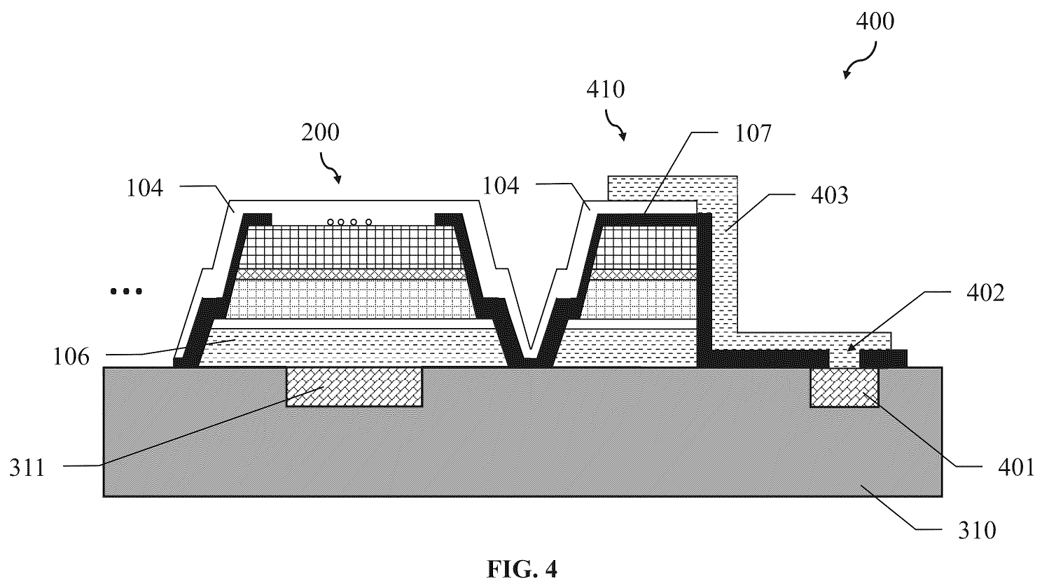

FIG. 4 illustrates a structural diagram showing a sectional view of another exemplary micro LED display panel 400, according to some embodiments of the present disclosure. As shown in FIG. 4, a micro LED element 410 at an edge (e.g., right edge) of micro LED display panel 400 is cut in half to enable conductively coupling the effective micro LED elements 200 on IC backplane 310 to an electrode 401 (e.g., a common pad). The cut micro LED elements will be ineffective for emitting and are also referred to as ineffective micro LED element 410 herein, while others can be called effective micro LED elements 200 (e.g., corresponding to micro LED elements 200 described above with reference to FIG. 2). At the edge of micro LED display panel 400, the deposited passivation layer 107 of ineffective micro LED elements 410 can be extended to the top surface of IC backplane 310 leaving a hole 402 above electrode 401. Above passivation layer 107 of ineffective micro LED elements 410, a conductive layer 403 is further formed, which also fills in hole 402 and conductively connects with electrode 401 and transparent conductive layer 104 of ineffective micro LED elements.

As transparent conductive layers 104 of effective micro LED elements and ineffective micro LED elements are connected together, transparent conductive layer 104 of each effective micro LED element 200 is connected to electrode 401 and contact pad 106 of each effective micro LED element 200 is connected to a corresponding electrode 311 of IC backplane 310, respectively. This enables first semiconductor layer 101 and second semiconductor layer 103 of each effective micro LED elements 200 to receive signals from IC backplane 310. As a consequence, light emitting layer 102 between first semiconductor layer 101 and second semiconductor layer 103 of each effective micro LED elements 200 can then be driven by IC backplane 310.

The other aspects of micro LED display panel 400 can be referred to micro LED display panel 300A described above with reference to FIG. 3A and will not be described in detail here. Similarly, the routine described here can also be applied to micro LED display panel 300B described above with reference to FIG. 3B.

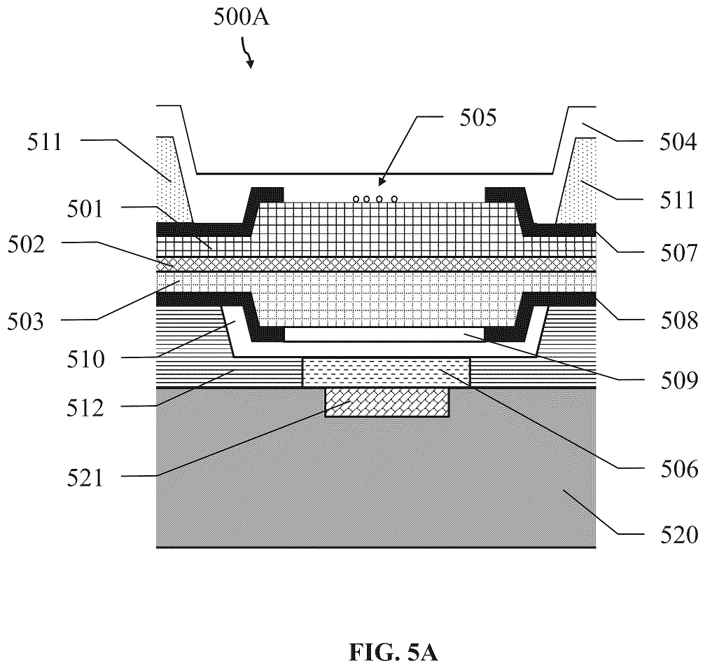

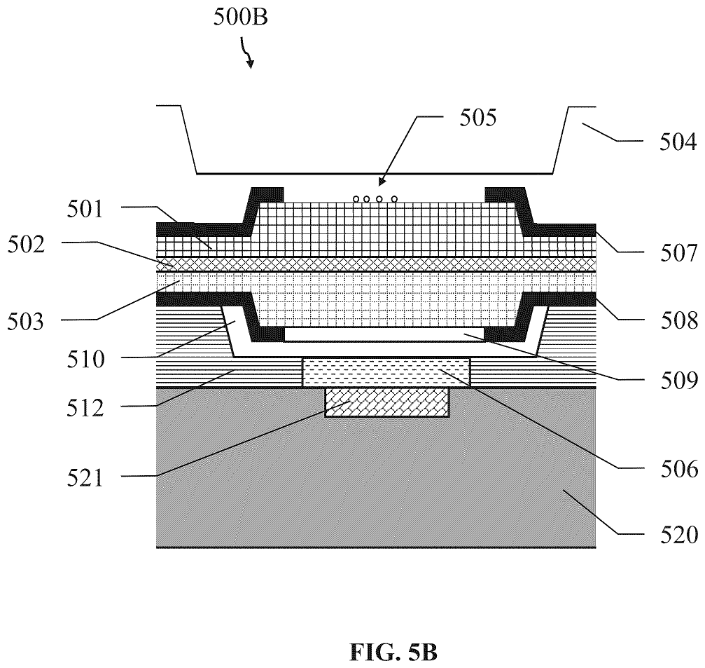

FIG. 5A illustrates a structural diagram showing a sectional view of another exemplary micro LED element 500A, according to some embodiments of the present disclosure. Referring to FIG. 5A, micro LED element 500A includes a first semiconductor layer 501, a light emitting layer 502, and a second semiconductor layer 503. First semiconductor layer 501, light emitting layer 502, and second semiconductor layer 503 are stacked from top down to form a mesa with a different shape compared to that shown in FIGS. 1-4. As shown in FIG. 5A, the mesa is formed into an olive shape with respective first semiconductor layer 501 and second semiconductor layer 503 decreasing in thickness at their ends and on either side of light emitting layer 502. Hence, the corresponding mid-portions of first semiconductor layer 501 and second semiconductor layer 503 are thicker than corresponding end portions.

As shown in FIG. 5A, micro LED element 500A further includes a transparent conductive layer 504 formed on a top surface of first semiconductor layer 501 and conductively coupled to first semiconductor layer 501. Micro LED element 500A further includes a metal contact 505 embedded in transparent conductive layer 504 which acts as an ohmic contact to increase the electrical conductivity between first semiconductor layer 501 and transparent conductive layer 504. Transparent conductive layer 504 can be connected to an electrode (not shown) of IC backplane 520. As shown in FIG. 5A, micro LED element 500A further includes a contact pad 506 that is connected to an electrode 521 (e.g., a Cu pad) of IC backplane 520. Hence, transparent conductive layer 504 and contact pad 506 are connected to two electrodes of IC backplane 520. This enables first semiconductor layer 501 and second semiconductor layer 503 to receive signals from IC backplane 520. As a consequence, light emitting layer 502 between first semiconductor layer 501 and second semiconductor layer 503 can be driven by the signals from IC backplane 520.

As illustrated in FIG. 5A, metal contact 505 includes a plurality of metal particles (also referred to as “metal agglomeration”, which is denoted by hollow circles) conductively coupled to the top surface of first semiconductor layer 501. For example, micro LED element 500A can be a red micro LED element used to represent a red pixel or sub-pixel. In some embodiments, the presence of metal contact as a whole pad in red micro LED element can result in an undesirable shading effect, a decrease in light extraction, or a blurred far-field beam profile. With the introduction of metal contact 505 composed of metal particles, the contacting area with first semiconductor layer 501 can be reduced while maintaining the ohmic-contact.

Moreover, the introduction of metal contact 505 including metal particles will increase the proportion of light within a divergence angle (e.g., twenty degrees) of micro LED element 500A. Consequently, an improvement in light energy power and an increase in light extraction efficiency can be expected at a viewer's eye. For example, when micro LED element 500A is incorporated into a pair of AR/VR glasses, the divergence angle of micro LED element 500A is concentrated when coupling to a waveguide of the AR/VR glasses.

The metal contact 505 having metal particles can be formed in a variety of ways. For example, the metal particles can be deposited on first semiconductor layer 501 by sputtering. As another example, the metal particles can be chemically etched from a metal pad attached to first semiconductor layer 501. Moreover, the metal particles can also be produced by melting a metal pad on first semiconductor layer 501. In some embodiments, a thickness of metal contact 505 having metal particles can be less than 100 nm. That is, the height of each metal agglomeration constructing metal contact 505 can be less than 100 nm.

In some embodiments and with reference to the above description of object size as used herein, a size of each metal particle can be less than 500 nm.

In some embodiments, a distribution diameter of the metal particles in transparent conductive layer 504 is within a range from 700 nm to 800 nm. That is, the metal particles are generated and distributed within a generally circular area with a diameter of 700 nm to 800 nm (e.g., 720 nm, 750 nm, or 780 nm) on the top surface of first semiconductor layer 501.

In some embodiments, a distribution density of the metal particles in transparent conductive layer 504 is within a range from 10/μm² to 10000/μm². For example, there can be thirty particles generated and distributed within an area of one μm² on the top surface of first semiconductor layer 501.

As shown in FIG. 5A, light emitting layer 502 separates micro LED element 500A into two isolated parts. As for the part above light emitting layer 502, a passivation layer 507 is formed on a sidewall surface of first semiconductor layer 501. As for the part below light emitting layer 502, a passivation layer 508 is formed on a sidewall surface of second semiconductor layer 503. Passivation layers 507 and 508 can provide electrical insulation to the component they cover. The thickness of passivation layer 507 (508) is in a range of 3 nm to 15 nm for a bule micro LED element 500A or a green micro LED element 500A, e.g., the thickness of passivation layer 507 (508) can be 3 nm, 4 nm, 5 nm, 6 nm, 7 nm, 8 nm, 9 nm, 10 nm, 11 nm, 12 nm, 13 nm, 14 nm, or 15 nm. Alternatively, the thickness of passivation layer 507 (508) can be several hundred nanometers for a red micro LED element 500A. In some examples, passivation layer 507 (508) is an ALD-based layer or formed by plasma-enhanced chemical vapor deposition (PECVD). A material of passivation layer 507 (508) can be selected from one or more of Al₂O₃, HfN, SiO₂, or SiN. Passivation layer 507 (508) is used as a thin dielectric layer. It prevents shorting of N-type epitaxial layer and P-type epitaxial layer and passivates dangling bonds on sidewalls to reduce leakage current in micro LED element 500A. As shown in FIG. 5A, passivation layer 507 can also be deposited in a region of the top surface of first semiconductor layer 501. In some embodiments, in the process of depositing transparent conductive layer 504, it can be then formed on the top surface of first semiconductor layer 501 in the region that is not deposited with passivation layer 507.

Still referring to FIG. 5A, micro LED element 500A further includes a transparent conductive layer 509 for conductively connecting second semiconductor layer 503 and contact pad 506 through a metal reflective layer 510 further described below. For example, contact pad 506 can be formed below transparent conductive layer 509. In some embodiments, second semiconductor layer 503 is formed on a top surface of transparent conductive layer 509. Light emitting layer 502 is formed on second semiconductor layer 503, and first semiconductor layer 501 is formed on light emitting layer 502. Second semiconductor layer 503 can be a P-type epitaxial layer or an N-type epitaxial layer. First semiconductor layer 501 is an N-type epitaxial layer or a P-type epitaxial layer. A material of first semiconductor layer 501 is one or more of GaN, InGaN, AlInGaN, AlGaN, GaP, AlGaInP, or AlInP. Light emitting layer 502 is a quantum well layer. A material of light emitting layer 502 is selected from one or more of InGaN, AlGaN, AlInGaN, InGaP or AlGaInP. First semiconductor layer 501 and second semiconductor layer 503 have opposite conductive types. That is, if first semiconductor layer 501 is a P-type epitaxial layer, then second semiconductor layer 503 is an N-type epitaxial layer; and if first semiconductor layer 501 is an N-type epitaxial layer, then second semiconductor layer 503 is a P-type epitaxial layer. A material of second semiconductor layer 503 is selected from one or more of AlInP, AlGaInP, GaP, GaN, InGaN, AlInGaN or AlGaN.

In some embodiments, transparent conductive layer 509 is provided as a TCO (transparent conductive oxide) layer, for example, an ITO (Indium Tin Oxide) layer, an AZO (Aluminium doped Zinc Oxide) layer, a GZO (Gallium doped Zinc Oxide), an ATO (Antimony doped Tin Oxide) layer, an FTO (Fluorine doped Tin Oxide) layer, or the like. Transparent conductive layer 504 can be formed with the same material as transparent conductive layer 509.

Micro LED element 500A further includes metal reflective layer 510 formed on a bottom surface of second transparent conductive layer 509, wherein contact pad 506 is formed on a bottom surface of the metal reflective layer 510. To improve light emission efficiency, metal reflective layer 510 is provided to reflect light upwards as viewed in FIG. 5A. Metal reflective layer 150 may be made of Ag, Al, Au, etc., and coated with one or more of Cr, Ni, Pt, Ti, or Au. In some embodiments, metal reflective layer 510 is further extended to and formed on a surface of passivation layer 508.

Micro LED element 500A may further include a metal pad 511 embedded in transparent conductive layer 504. Metal pad 511 can be used to increase current expansion between adjacent micro LED elements 500A and subsequently improve current spreading across the whole Micro LED array described below.

With further reference to FIG. 5A, micro LED element 500A further includes an insulating layer 512 formed on IC backplane 520. Insulating layer 512 covers IC backplane 520 and provides insulation to surface components of IC backplane 520. The other aspects of micro LED element 500A can be understood by referring to the description of micro LED elements 100 and micro LED elements 200 described above with reference to FIGS. 1 and 2 and will not be described in detail here.

In some embodiments, metal pads 511 embedded between adjacent micro LED elements 500A can be omitted. FIG. 5B illustrates a structural diagram showing a sectional view of another exemplary micro LED element 500B, according to some embodiments of the present disclosure. As shown in FIG. 5B, the conductivity of adjacent micro LED elements 500B can be realized by transparent conductive layer 504 of adjacent micro LED elements 500B, which can be connected to form a continuous layer.

The other aspects of micro LED element 500B can be understood by referring to the description of micro LED element 500A with reference to FIG. 5A and will not be described in detail here.

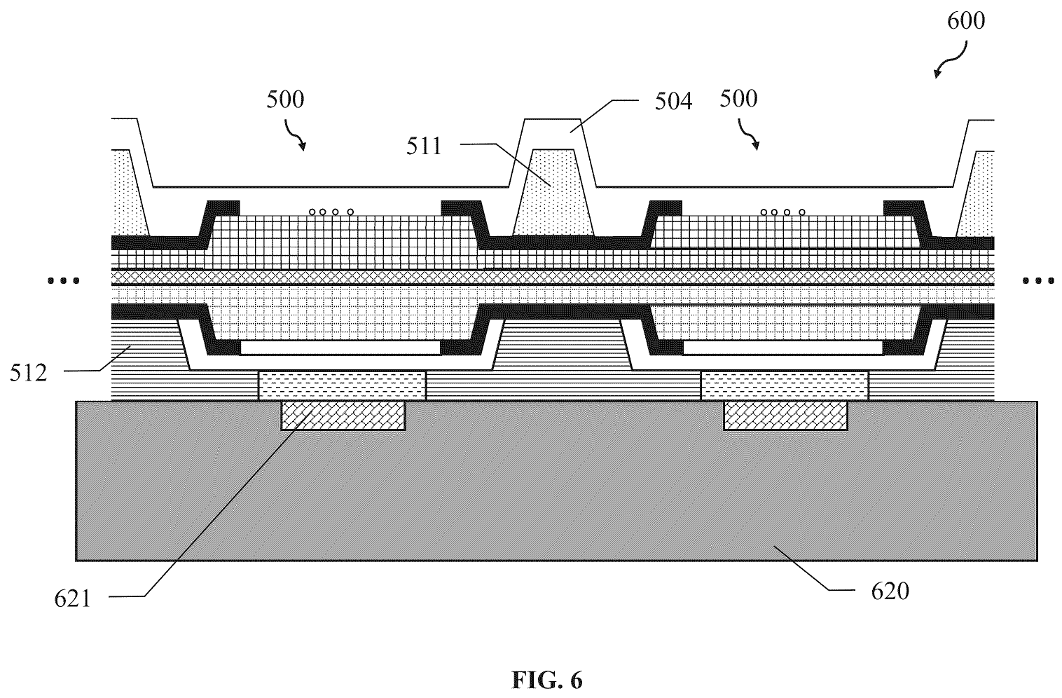

FIG. 6 illustrates a structural diagram showing a sectional view of another exemplary micro LED display panel 600, according to some embodiments of the present disclosure. As shown in FIG. 6, micro LED display panel 600 includes an IC backplane 620 (e.g., corresponding to IC backplane 520 in FIG. 5A). A plurality of electrodes 621 (e.g., corresponding to electrode 521 in FIG. 5A) are embedded in IC backplane 620 such that one electrode corresponds to one micro LED element 500A. Micro LED display panel 600 further includes a plurality of micro LED elements 500A as described above with reference to FIG. 5A. Each of the plurality of micro LED elements 500A is disposed on a top surface of IC backplane 620. The top surface of IC backplane 620 is a surface that can be provided as a substrate for arranging components. As can be appreciated, the top surface, or its corresponding bottom surface on the opposite side, is typically larger than other sides of the IC backplane. Metal pad 511 embedded in transparent conductive layer 504 and between adjacent micro LED elements 500A can be used to increase current expansion between adjacent micro LED elements 500A.

It can be understood that in FIG. 6, micro LED display panel 600 including two micro LED elements 500A is shown only for illustrative purposes. The structure shown can be extended to form a complete micro LED display panel 600. Micro LED display panel 600 further includes an insulating layer 512 formed on IC backplane 620 between each of the plurality of micro LED elements 500A. Insulating layer 512 can cover IC backplane 620 and provides insulation to surface components of IC backplane 620. As can be appreciated, each micro LED element 500A of micro LED display panel 600 can be connected to two electrodes of IC backplane 620 in a similar manner to that shown in FIG. 4.

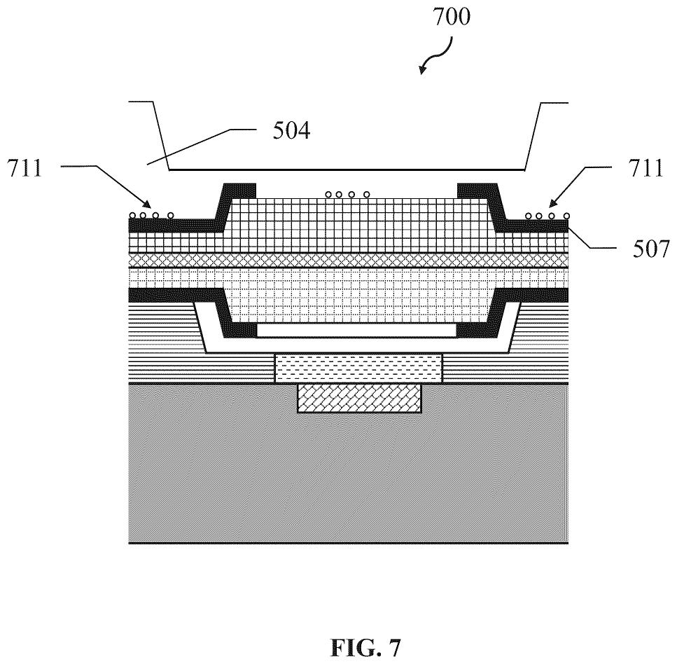

FIG. 7 illustrates a structural diagram showing a sectional view of another exemplary micro LED element 700, according to some embodiments of the present disclosure. As described above with reference to FIG. 5A, metal pad 511 embedded in transparent conductive layer 504 can be used to increase current expansion between adjacent micro LED elements 500A. However, light emitted from first semiconductor layer 501 can diverge in a relatively large angle and some of the light can be reflected by metal pad 511, ultimately leading to the manifestation of a shading effect. As shown in FIG. 7, micro LED element 700 further includes a metal contact 711 embedded in transparent conductive layer 504 for replacing metal pad 511. Metal contact 711 includes a plurality of metal particles (also referred to as a “metal agglomeration”, which is denoted by hollow circles in FIG. 7) formed on a top surface of passivation layer 507. With the introduction of metal contact 711 composed of metal particles, the shading effect can be reduced further while maintaining current expansion between adjacent micro LED elements 700. The other aspects of micro LED element 700 can be understood by referring to the description of micro LED element 500A and will not be described in detail here.

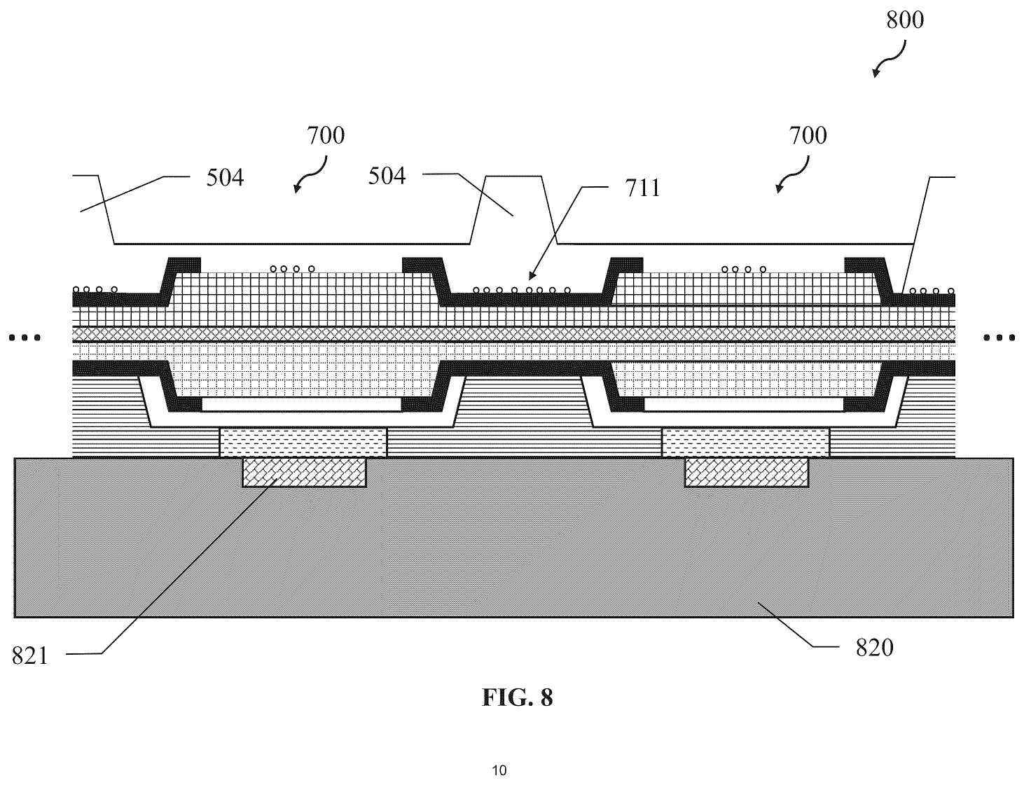

FIG. 8 illustrates a structural diagram showing a sectional view of another exemplary micro LED display panel 800, according to some embodiments of the present disclosure. Similar to micro LED display panel 600 shown in FIG. 6, micro LED display panel 800 includes an IC backplane 820 on which are disposed a plurality of micro LED elements 700. A plurality of electrodes 821 are embedded in IC backplane 820 such that one electrode corresponds to one micro LED element 700. A metal contact 711 embedded in transparent conductive layer 504 can be used to increase current expansion between adjacent micro LED elements 700. It is appreciated that in FIG. 8, micro LED display panel 800 including two micro LED elements 700 is shown only for illustrative purposes. The structure shown can be extended to form a complete micro LED display panel 800. The other aspects of micro LED display panel 800 can be understood by referring to the description of micro LED display panel 600 and will not be described in detail here.

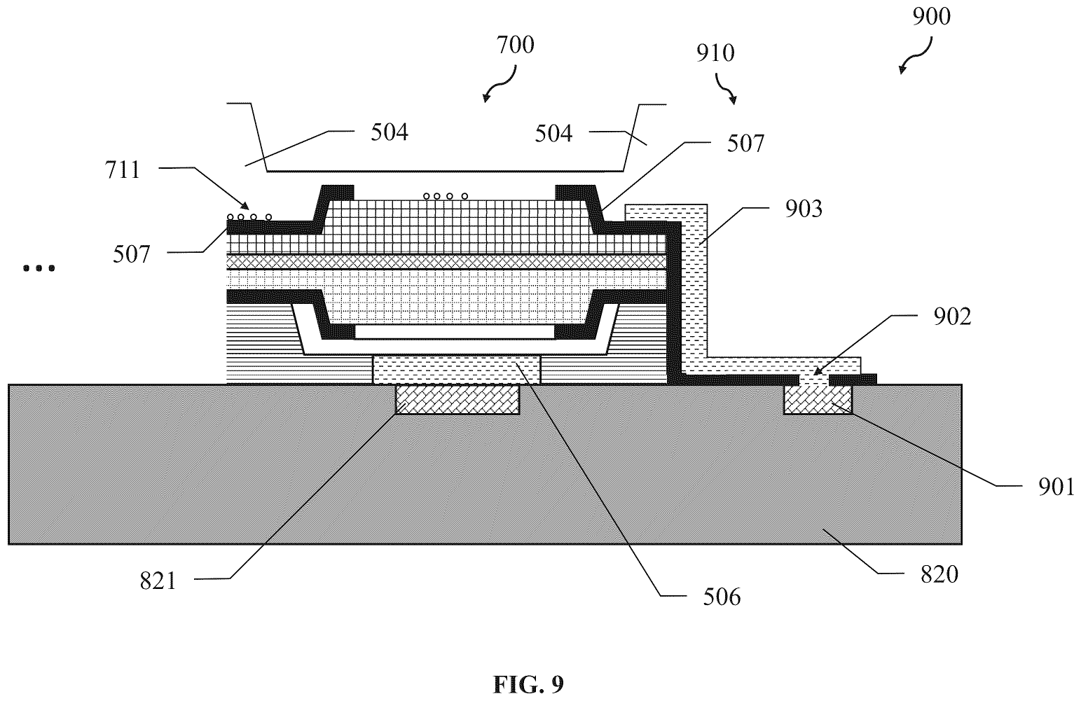

FIG. 9 illustrates a structural diagram showing a sectional view of an exemplary micro LED display panel 900, according to some embodiments of the present disclosure. As shown in FIG. 9, a connecting part 910 at an edge (e.g., right edge) of micro LED display panel 900 is used for conductively coupling the micro LED elements 700 on IC backplane 820 to an electrode 901 (e.g., a common pad). At the edge of micro LED display panel 900, the deposited passivation layer 507 of micro LED elements 700 can be extended to the top surface of IC backplane 820 leaving a hole 902 above electrode 901. Above passivation layer 507 of connecting part 910, a conductive layer 903 is further formed, which also fills in hole 902 and conductively connects with electrode 901 and transparent conductive layer 504.

As such, transparent conductive layer 504 of each effective micro LED element 700 is connected to electrode 901 and contact pad 506 of each micro LED element 700 is connected to electrode 821 of IC backplane 820, respectively. This enables first semiconductor layer 501 and second semiconductor layer 503 of each effective micro LED elements 700 to receive signals from IC backplane 820. As a consequence, light emitting layer 502 between first semiconductor layer 501 and second semiconductor layer 503 of each micro LED elements 700 can then be driven by IC backplane 820.

The other aspects of micro LED display panel 900 can be understood by referring to micro LED display panel 800 described above with reference to FIG. 8 and will not be described in detail here.

In some embodiments, each micro LED element (e.g., micro LED element 100 in FIG. 1, micro LED element 200 in FIG. 2, micro LED element 500A in FIG. 5A, micro LED element 500B in FIG. 5B, or micro LED element 700 in FIG. 7) herein has a very small volume. The light emitting area of the micro LED display panel (e.g., micro LED display panel 300A in FIG. 3A, micro LED display panel 300B in FIG. 3B, micro LED display panel 400 in FIG. 4, micro LED display panel 600 in FIG. 6, or micro LED display panel 800 in FIG. 8) is very small, such as 1 mm×1 mm, 3 mm×5 mm, etc. In some embodiments, the light emitting area of micro LED display panel can be less than or equal to or near 0.15 cm², 0.25 cm², or 1 cm². In some embodiments, the light emitting area is the area of the micro LED array area in the micro LED display panel. Each micro LED display panel disclosed herein, e.g., Micro LED display panel 700, includes one or more micro LED elements that form a pixel array in which the micro LED elements are pixels, such as a 1600×1200, 680×480, or 1920×1080-pixel array. The diameter of each micro LED is in the range of about 200 nm to 2 μm.

Different types of micro LED panels can be provided. For example, the resolution of a display panel can range typically from 8×8 to 3840×2160. Common display resolutions include QVGA (Quarter Video Graphics Array) with 320×240 resolution and an aspect ratio of 4:3, XGA (Extended Graphics Array) with 1024×768 resolution and an aspect ratio of 4:3, D (Definition) with 1280×720 resolution and an aspect ratio of 16:9, FHD (Full High Definition) with 1920×1080 resolution and an aspect ratio of 16:9, UHD (Ultra High Definition) with 3840×2160 resolution and an aspect ratio of 16:9, and 4K with 4096×2160 resolution. There can also be a wide variety of pixel sizes, ranging from sub-micron and below to 10 mm and above. The size of the overall display region can also vary widely, ranging from diagonals as small as tens of microns or less up to hundreds of inches or more.

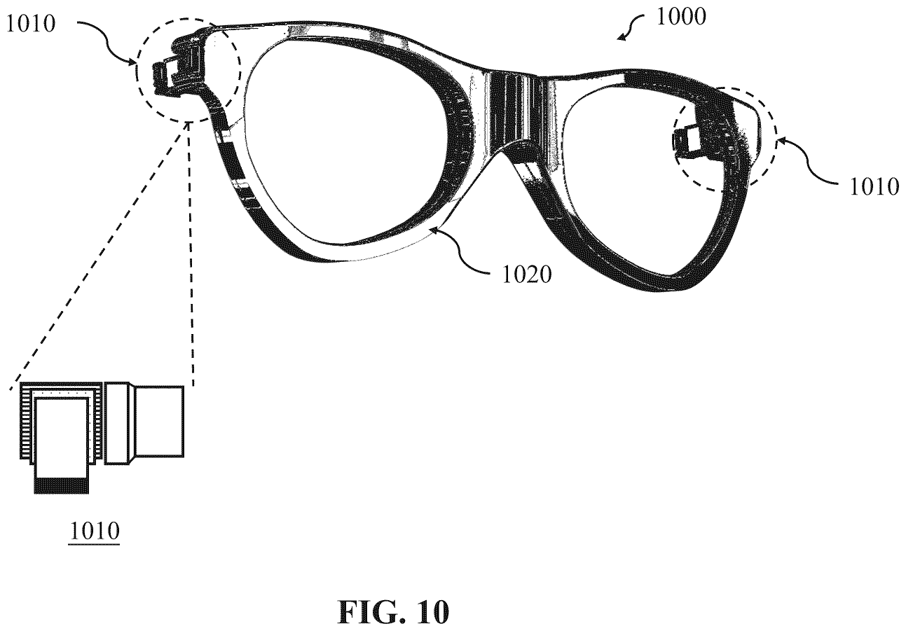

FIG. 10 illustrates an exemplary display device, according to some embodiments of the present disclosure. As shown in FIG. 10, a near eye display (NED) 1000, for example AR glasses, includes a pair of polychrome projectors 1010 and a frame 1020 for securing polychrome projectors 1010. NED 1000 may also include other components which are omitted here for the purpose of clearly illustrating the configuration of NED 1000. Each polychrome projector 1010 can be arranged at an end of a temple (not shown) of NED 1000, respectively. A power system and a processing system to drive polychrome projectors 1010 can be embedded in the temple. Images rendered by each polychrome projector 1010 can be captured by respective eyes of a viewer (not shown), which can be used to create a virtual scene or an augmented scene for the viewer. In some embodiments, the term “render” may also be referred to as “display,” “show” or an equivalent. Each polychrome projector 1010 may include three micro LED panels (e.g., each corresponding to micro LED display panel 300A in FIG. 3A, micro LED display panel 300B in FIG. 3B, micro LED display panel 400 in FIG. 4, micro LED display panel 600 in FIG. 6, or micro LED display panel 800 in FIG. 8) of different colors and a combiner (e.g., a combining prism). Combiner can be used to combine (also referred to as “compositing”) the images rendered the three micro LED panels to a composite image.

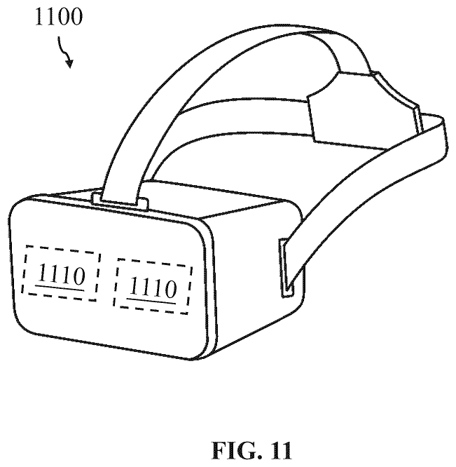

FIG. 11 illustrates another exemplary display device, according to some embodiments of the present disclosure. As shown in FIG. 11, a head-mounted virtual reality device 1100 includes two micro LED panels 1110 (e.g., corresponding to micro LED display panel 300A in FIG. 3A, micro LED display panel 300B in FIG. 3B, micro LED display panel 400 in FIG. 4, micro LED display panel 600 in FIG. 6, or micro LED display panel 800 in FIG. 8). Although not shown, head-mounted virtual reality device 1100 may also include a central processing unit (CPU), a graphic processing unit (GPU) acting as a signal source, and other related circuitries. The introduction of micro LED panels that embody the micro LED elements described above in head-mounted virtual reality device 1100 can improve the lighting efficiency thereof, hence reducing energy consumption and improving imaging quality.

The embodiments may further be described using the following clauses:
1. A micro LED element, including:
a first semiconductor layer, a light emitting layer, and a second semiconductor layer stacked from top down; and
a metal contact including a plurality of metal particles conductively coupled to the top surface of the first semiconductor layer.
2. The micro LED element according to clause 1, wherein a thickness of the metal contact is less than 100 nm.
3. The micro LED element according to clause 1 or 2, wherein a size of each of the plurality of metal particles is less than 500 nm.
4. The micro LED element according to any of clauses 1 to 3, further comprising:
a transparent conductive layer formed on a top surface of the first semiconductor layer, wherein the metal contact is embedded in the transparent conductive layer; and
a contact pad conductively coupled to the second semiconductor layer.
5. The micro LED element according to clause 4, wherein a distribution diameter of the plurality of metal particles in the transparent conductive layer is within a range from 700 nm to 800 nm.
6. The micro LED element according to clause 4 or 5, wherein a distribution density of the plurality of metal particles in the transparent conductive layer is within a range from 10/μm² to 10000/μm².
7. The micro LED element according to any of clauses 4 to 6, wherein the first semiconductor layer, the light emitting layer, and the second semiconductor layer are stacked as a mesa; and the micro LED element further includes:
a passivation layer formed on a sidewall surface of the mesa.
8. The micro LED element according to clause 7, wherein the passivation layer is an ALD (Atomic Layer Deposition)-based layer.
9. The micro LED element according to clause 7, wherein a diameter of a top surface of the mesa is smaller than a diameter of a bottom surface of the mesa.
10. The micro LED element according to clause 7, wherein the transparent conductive layer is further formed on a surface of the passivation layer.
11. The micro LED element according to clause 7, wherein the mesa further includes: a second transparent conductive layer formed on a bottom surface of the second semiconductor layer, wherein the contact pad is formed on a bottom surface of the second transparent conductive layer.
12. The micro LED element according to any of clauses 4 to 6, further including:
a first passivation layer formed on a first sidewall surface of the first semiconductor layer; and
a second passivation layer formed on a second sidewall surface of the second semiconductor layer.
13. The micro LED element according to clause 12, wherein at least one of the first passivation layer and the second passivation layer is an ALD-based layer.
14. The micro LED element according to clause 12, further including: a second transparent conductive layer formed on a bottom surface of the second semiconductor layer, wherein the contact pad is formed below the second transparent conductive layer.
15. The micro LED element according to clause 14, further including: a metal reflective layer formed on a bottom surface of the second transparent conductive layer, wherein the contact pad is formed on a bottom surface of the metal reflective layer.
16. The micro LED element according to clause 15, wherein the metal reflective layer is further formed on a surface of the second passivation layer.
17. The micro LED element according to clause 12, further including: a second metal contact embedded in the transparent conductive layer, the second metal contact including a plurality of metal particles formed on a top surface of the first passivation layer.
18. A micro LED display panel, including:
an integrated circuit (IC) backplane including a common pad and a plurality of bottom contacts; and
a plurality of micro LED elements disposed on a top surface of the IC backplane, each according to any of clauses 1 to 17, and wherein:
   the transparent conductive layer is conductively coupled to the common pad; and
   the contact pad is formed to contact a corresponding bottom contact of the plurality of bottom contacts.
19. A display device, including the micro LED element according to any of clauses 1 to 17, or the micro LED display panel according to clause 18.

It should be noted that the relational terms herein such as “first” and “second” are used only to differentiate an entity or operation from another entity or operation, and do not require or imply any actual relationship or sequence between these entities or operations. Moreover, the words “comprising,” “having,” “containing,” and “including,” and other similar forms are intended to be equivalent in meaning and be open ended in that an item or items following any one of these words is not meant to be an exhaustive listing of such item or items, or meant to be limited to only the listed item or items.

As used herein, unless specifically stated otherwise, the term “or” encompasses all possible combinations, except where infeasible. For example, if it is stated that a database may include A or B, then, unless specifically stated otherwise or infeasible, the database may include A, or B, or A and B. As a second example, if it is stated that a database may include A, B, or C, then, unless specifically stated otherwise or infeasible, the database may include A, or B, or C, or A and B, or A and C, or B and C, or A and B and C.

In the foregoing specification, embodiments have been described with reference to numerous specific details that can vary from implementation to implementation. Certain adaptations and modifications of the described embodiments can be made. Other embodiments can be apparent to those skilled in the art from consideration of the specification and practice of the invention disclosed herein. It is intended that the specification and examples be considered as exemplary only, with a true scope and spirit of the invention being indicated by the following claims. It is also intended that the sequence of steps shown in figures are only for illustrative purposes and are not intended to be limited to any particular sequence of steps. As such, those skilled in the art can appreciate that these steps can be performed in a different order while implementing the same method.

In the drawings and specification, there have been disclosed exemplary embodiments. However, many variations and modifications can be made to these embodiments. Accordingly, although specific terms are employed, they are used in a generic and descriptive sense only and not for purposes of limitation.

What is claimed is:

1. A micro LED element, comprising:
a first semiconductor layer, a light emitting layer, and a second semiconductor layer stacked from top down; and
a metal contact comprising a plurality of metal particles conductively coupled to the top surface of the first semiconductor layer.

2. The micro LED element according to claim 1, wherein a thickness of the metal contact is less than 100 nm.

3. The micro LED element according to claim 1, wherein a size of each of the plurality of metal particles is less than 500 nm.

4. The micro LED element according to claim 1, further comprising:
a transparent conductive layer formed on a top surface of the first semiconductor layer, wherein the metal contact is embedded in the transparent conductive layer; and
a contact pad conductively coupled to the second semiconductor layer.

5. The micro LED element according to claim 4, wherein a distribution diameter of the plurality of metal particles in the transparent conductive layer is within a range from 700 nm to 800 nm.

6. The micro LED element according to claim 4, wherein a distribution density of the plurality of metal particles in the transparent conductive layer is within a range from 10/μm² to 10000/μm².

7. The micro LED element according to claim 4, wherein the first semiconductor layer, the light emitting layer, and the second semiconductor layer are stacked as a mesa; and the micro LED element further comprises:
a passivation layer formed on a sidewall surface of the mesa.

8. The micro LED element according to claim 7, wherein the passivation layer is an ALD (Atomic Layer Deposition)-based layer.

9. The micro LED element according to claim 7, wherein a diameter of a top surface of the mesa is smaller than a diameter of a bottom surface of the mesa.

10. The micro LED element according to claim 7, wherein the transparent conductive layer is further formed on a surface of the passivation layer.

11. The micro LED element according to claim 7, wherein the mesa further comprises: a second transparent conductive layer formed on a bottom surface of the second semiconductor layer, wherein the contact pad is formed on a bottom surface of the second transparent conductive layer.

12. The micro LED element according to claim 4, further comprising:
a first passivation layer formed on a first sidewall surface of the first semiconductor layer; and
a second passivation layer formed on a second sidewall surface of the second semiconductor layer.

13. The micro LED element according to claim 12, wherein at least one of the first passivation layer and the second passivation layer is an ALD-based layer.

14. The micro LED element according to claim 12, further comprising: a second transparent conductive layer formed on a bottom surface of the second semiconductor layer, wherein the contact pad is formed below the second transparent conductive layer.

15. The micro LED element according to claim 14, further comprising: a metal reflective layer formed on a bottom surface of the second transparent conductive layer, wherein the contact pad is formed on a bottom surface of the metal reflective layer.

16. The micro LED element according to claim 15, wherein the metal reflective layer is further formed on a surface of the second passivation layer.

17. The micro LED element according to claim 12, further comprising: a second metal contact embedded in the transparent conductive layer, the second metal contact comprising a plurality of metal particles formed on a top surface of the first passivation layer.

18. A micro LED display panel, comprising:
an integrated circuit (IC) backplane comprising a common pad and a plurality of bottom contacts; and
a plurality of micro LED elements each according to claim 1 disposed on a top surface of the IC backplane, and wherein:
a transparent conductive layer of each of the plurality of micro LED elements is conductively coupled to the common pad; and
a contact pad of each of the plurality of micro LED elements is formed to contact a corresponding bottom contact of the plurality of bottom contacts.

19. A display device, comprising a micro LED element, wherein the micro LED element comprises:
a first semiconductor layer, a light emitting layer, and a second semiconductor layer stacked from top down; and
a metal contact comprising a plurality of metal particles conductively coupled to the top surface of the first semiconductor layer.
